(19) United States
(12) Patent Application Publication
(10) Pub. No.: US 2019/0355906 A1
(43) Pub. Date: Nov. 21, 2019

(54) VAPOR DEPOSITION METHOD, AND EL DEVICE MANUFACTURING METHOD

(71) Applicant: Sharp Kabushiki Kaisha, Sakai City, Osaka (JP)

(72) Inventors: Shinsaku NAKAJIMA, Sakai City (JP); Seiji FUJIWARA, Sakai City (JP)

(21) Appl. No.: 16/462,284

(22) PCT Filed: May 19, 2017
(86) PCT No.: PCT/JP2017/018890

§ 371 Date: May 20, 2019

(51) Int. Cl. H01L 51/00; C23C 14/04; H01L 51/56; H01L 27/32

(52) U.S. Cl. CPC H01L 51/0011; C23C 14/042; H01L 27/3244; H01L 51/56; H01L 27/323; H01L 51/001

(57) ABSTRACT

A vapor deposition method includes a fixing step for fixing a vapor deposition mask on a mask frame, a lifting step for mounting a substrate on the vapor deposition mask and lifting the mask frame to bring the substrate into contact with a touch plate disposed above the mask frame, and a measurement step for measuring a thickness of the mask frame. The lifting step includes determining a lifting amount of the mask frame on the basis of the thickness of the mask frame measured by the measurement step.

### TECHNICAL FIELD

The disclosure relates to a vapor deposition method for vapor-depositing a vapor deposition layer onto a substrate through a vapor deposition mask fixed on a mask frame, a vapor deposition apparatus, an EL device manufacturing apparatus, and an EL device manufacturing method.

### BACKGROUND ART

There have been known vapor deposition methods for forming a vapor deposition layer on a substrate from a vapor deposition source through a vapor deposition mask (PTL 1). In this vapor deposition method, a vapor deposition material is vapor-deposited onto a substrate surface through an opening of the vapor deposition mask disposed facing the substrate to form a predetermined pattern. A substrate holding portion configured to hold the substrate is provided with a plurality of electrostatic chucks that electrostatically attract and hold the substrate. These electrostatic chucks are each provided with a piezoelectric element on an end face on a side opposite to the attracting face side.

Then, a flatness of the substrate surface is measured by a laser displacement meter. Next, the flatness of the substrate surface measured by the laser displacement meter is fed back to the plurality of electrostatic chucks and the piezoelectric elements of the electrostatic chucks are individually driven to control a protrusion amount of each of the electrostatic chucks. As a result, the flatness of the substrate surface facing the vapor deposition mask becomes substantially uniform.

### CITATION LIST

### Patent Literature

PTL 1: JP 2010-261081 A (published on Nov. 18, 2010)

### SUMMARY

### Technical Problem

In a vapor deposition process for forming an organic light emitting diode (OLED) on a substrate, a mask frame with a vapor deposition mask fixed by welding on which a substrate is mounted is lifted by a lifting apparatus until the substrate comes into contact with a touch plate disposed above the mask frame. Then, a luminescent material is formed on the substrate via a through-hole of the vapor deposition mask from the vapor deposition source disposed below the mask frame. The lifting amount by which the mask frame is lifted is determined by a fixed setting value set in the lifting apparatus.

Nevertheless, an individual difference exists in a thickness of the mask frame due to the following causes. First, while the thickness of the mask frame itself has a specification range of ±50 μm, for example, variation in thickness exists in each individual mask frame, including mask frames having a thickness within the specification range and mask frames having a thickness outside the specification range.

Then, with repeated use of the vapor deposition mask, the luminescent material may adhere to the vapor deposition mask. In this case, the vapor deposition mask is removed from the mask frame and washed. Then, the mask frame with the vapor deposition mask removed is polished. Next, the washed vapor deposition mask is welded and fixed once again to the polished mask frame. With this polishing, the thickness of the mask frame changes, causing an individual difference (variation) in thickness to occur.

Further, with repeated use of the vapor deposition mask, the vapor deposition mask may need to be replaced due to a variety of reasons such as the vapor deposition mask bending and becoming damaged, the through-hole of the vapor deposition mask becoming deformed, or the luminescent material becoming jammed in the through-hole and irremovable. In this case, first the vapor deposition mask is removed from the mask frame. Then, the mask frame with the vapor deposition mask removed is polished. Next, the vapor deposition mask for replacement is welded and fixed to the polished mask frame. With this polishing as well, the thickness of the mask frame changes, causing an individual difference (variation) in thickness to occur.

As a result, a gap between the touch plate and the vapor deposition mask fixed to the mask frame lifted by the lifting amount defined by the fixed setting value may vary, leading to the problem that the vapor deposition quality is unstable.

### Solution to Problem

A vapor deposition method according to an aspect of the disclosure includes a fixing step for fixing a vapor deposition mask on a mask frame, a lifting step for mounting a substrate on the vapor deposition mask fixed on the mask frame and lifting the mask frame so to bring the substrate into contact with a touch plate disposed above the mask frame, and a measurement step for measuring a thickness of the mask frame.

The lifting step includes determining a lifting amount of the mask frame on the basis of the thickness of the mask frame measured by the measurement step.

### Advantageous Effects of Disclosure

According to an aspect of the disclosure, it is possible to provide a vapor deposition method, a vapor deposition apparatus, an EL device manufacturing apparatus, and an EL device manufacturing method that achieve a stable vapor deposition quality.

### BRIEF DESCRIPTION OF DRAWINGS

FIG. 1 is a schematic view illustrating a configuration of a vapor deposition apparatus according to a first embodiment.

FIG. 2 is a perspective view of a mask frame provided to the vapor deposition apparatus.

FIG. 3 is a perspective view illustrating the mask frame and a vapor deposition mask fixed to the mask frame.

FIG. 4 is a perspective view illustrating the vapor deposition mask fixed to the mask frame.

FIG. 5 is a cross-sectional view illustrating a relationship between the mask frame, the vapor deposition mask, a substrate, and a touch plate.

FIG. 6 is a schematic view illustrating a configuration of a vapor deposition apparatus according to a second embodiment.

FIG. 7A is a plan view of the mask frame and the vapor deposition mask provided to the vapor deposition apparatus, FIG. 7B is a plan view illustrating the details of a portion C of FIG. 7A, and FIG. 7C is a cross-sectional view for describing the details of the portion C in FIG. 7A.

### DESCRIPTION OF EMBODIMENTS

### First Embodiment

### Configuration of Vapor Deposition Apparatus 1

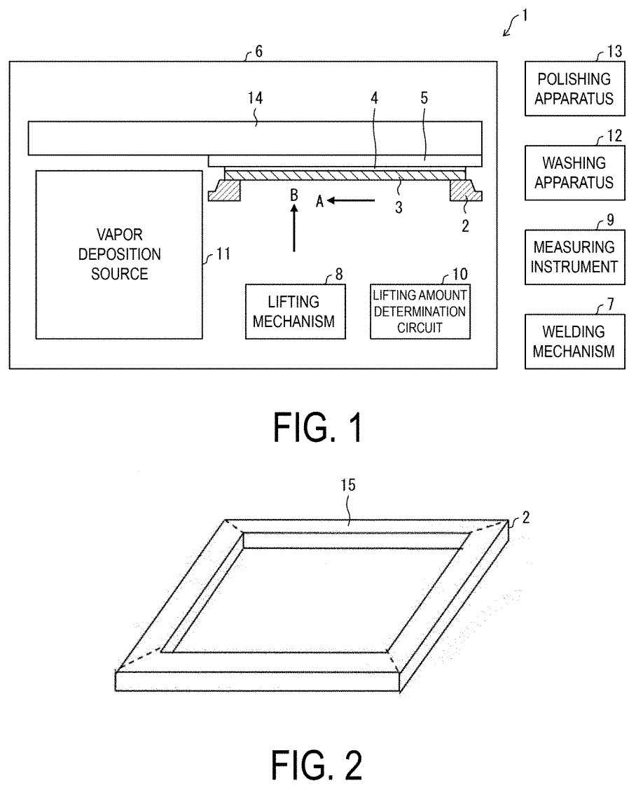

FIG. 1 is a schematic view illustrating a configuration of a vapor deposition apparatus 1 according to the first embodiment. The vapor deposition apparatus 1 includes a vacuum chamber 6. In the vacuum chamber 6, a substrate 4 is mounted on a vapor deposition mask 3 fixed on a mask frame 2, and a lifting mechanism 8 is provided in order to lift the mask frame 2 in a direction of an arrow B so to bring the substrate 4 into contact with a touch plate 5 disposed above the mask frame 2. A lifting amount of the mask frame 2 by the lifting mechanism 8 is from 0 to 5 mm, and preferably from 0 to 2 mm. A processing time required for lifting is from 1 to 2 seconds. A weight of the lifting mechanism 8 is approximately 1,000 kg. The vapor deposition mask 3 is made from a metal. A gap between the vapor deposition mask 3 and the substrate 4 is within 1 μm.

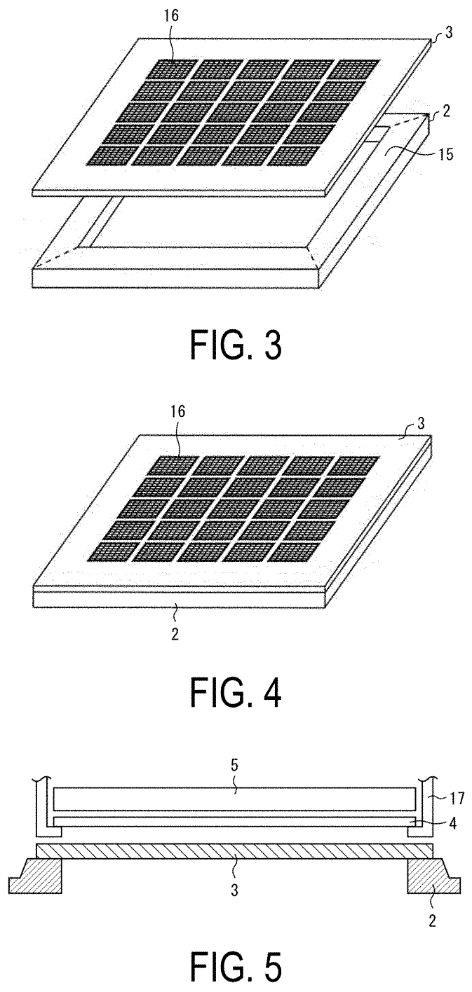

FIG. 2 is a perspective view of the mask frame 2. FIG. 3 is a perspective view illustrating the mask frame 2 and the vapor deposition mask 3 fixed to the mask frame 2. FIG. 4 is a perspective view illustrating the vapor deposition mask 3 fixed to the mask frame 2. The mask frame 2 has a shape of a rectangular frame body in which cross-piece members constituting four sides are welded at frame joining locations at the four corners. A joining face 15 is formed on the rectangular frame body. A weight of the mask frame 2 is about from 40 to 70 kg. The vapor deposition mask 3 has a thickness of from 20 to 30 μm, and includes many through-holes 16 for vapor deposition. The shape of the through-hole 16 can be changed according to the vapor deposition target. The vapor deposition mask 3 is fixed by welding to the joining face 15 of the mask frame 2 before delivery to the vacuum chamber 6. A dimension of one side of the vapor deposition mask 3 is, for example, 1,300 mm or greater. A measuring instrument 9 that measures a thickness of the mask frame 2 is arranged outside the vacuum chamber 6.

FIG. 5 is a cross-sectional view illustrating a relationship between the mask frame 2, the vapor deposition mask 3, the substrate 4, and the touch plate 5. The substrate 4 is mounted by a tab 17 on the vapor deposition mask 3 fixed on the mask frame 2. Then, the touch plate 5 is disposed above the mask frame 2. The mask frame 2 is lifted by the lifting mechanism 8, bringing the substrate 4 into contact with this touch plate 5. A magnet (not illustrated) for fixing the substrate 4 between the touch plate 5 and the vapor deposition mask 3 is provided on the touch plate 5.

A lifting amount determination circuit 10 that determines the lifting amount of the mask frame 2 on the basis of the thickness of the mask frame 2 measured by the measuring instrument 9 is provided in the vacuum chamber 6. Then, a transport mechanism 14 that transports the touch plate 5 with which the substrate 4 mounted on the vapor deposition mask 3 is brought into contact, and a vapor deposition source 11 that vapor-deposits a luminescent material through the vapor deposition mask 3 onto the substrate 4 brought into contact with the touch plate 5 transported by the transport mechanism 14 are provided inside the vacuum chamber 6.

A washing apparatus 12 that removes the vapor deposition mask 3 from the mask frame 2 and washes a portion of the luminescent material adhered to the vapor deposition mask 3, a polishing apparatus 13 that polishes the mask frame 2 with the vapor deposition mask 3 removed, and a welding mechanism 7 that once again welds and fixes the vapor deposition mask 3 washed by the washing apparatus 12 to the mask frame 2 polished by the polishing apparatus 13 are provided outside the vacuum chamber 6. The welding mechanism 7 may weld and fix the vapor deposition mask 3 for replacement to the mask frame 2 polished by the polishing apparatus 13.

The measuring instrument 9 may measure the thickness of the mask frame 2 before the vapor deposition mask 3 is fixed, or may measure the thickness of the mask frame 2 after the vapor deposition mask 3 is fixed.

### Action of Vapor Deposition Apparatus 1

First, the thickness of the mask frame 2 is measured by the measuring instrument 9. Then, the vapor deposition mask 3 is fixed on the mask frame 2 by welding. Subsequently, the substrate 4 is mounted on the vapor deposition mask 3 fixed on the mask frame 2. Next, the mask frame 2 to which the vapor deposition mask 3 provided with the substrate 4 is fixed is delivered into the vacuum chamber 6.

Subsequently, the lifting amount determination circuit 10 determines the lifting amount of the mask frame 2 on the basis of the thickness of the mask frame 2 measured by the measuring instrument 9. Next, the lifting mechanism 8 lifts the mask frame 2 on the basis of the lifting amount determined by the lifting amount determination circuit 10 so that the substrate 4 mounted on the vapor deposition mask 3 comes into contact with the touch plate 5.

Then, the luminescent material is vapor-deposited onto the substrate 4 by the vapor deposition source 11 through the vapor deposition mask 3 provided with the substrate 4 that comes into contact with the touch plate 5 transported by the transport mechanism 14.

Next, the vapor deposition mask 3 is removed from the mask frame 2, and a portion of the luminescent material adhered to the vapor deposition mask 3 is washed. Subsequently, the mask frame 2 with the vapor deposition mask 3 removed is polished by the polishing apparatus 13. Then, the thickness of the mask frame 2 polished by the polishing apparatus 13 is measured by the measuring instrument 9. Next, the vapor deposition mask 3 washed by the washing apparatus 12 is once again welded and fixed to the mask frame 2 measured for thickness by the measuring instrument 9.

Subsequently, the substrate 4 is mounted on the vapor deposition mask 3 welded once again to the mask frame 2, and delivered into the vacuum chamber 6. Then, the lifting amount determination circuit 10 determines the lifting amount of the mask frame 2 on the basis of the thickness of the mask frame 2 measured by the measuring instrument 9 after polishing. Next, the lifting mechanism 8 lifts the mask frame 2 on the basis of the lifting amount determined by the lifting amount determination circuit 10 so that the substrate 4 comes into contact with the touch plate 5.

Thus, the lifting amount of the mask frame 2 is determined on the basis of the thickness of the mask frame 2 measured by the measuring instrument 9. As a result, the variation in the gap between the touch plate 5 and the vapor deposition mask 3 fixed to the mask frame 2 caused by the variation in thickness based on the individual difference of the mask frame 2 itself is reduced. For example, when a dimensional tolerance of the thickness of the mask frame 2 during manufacture is 30.0 mm plus 0.2 mm, minus 0.0 mm, the lifting amount of the mask frame 2 is determined on the basis of the dimensional tolerance and the thickness of the mask frame 2 measured by the measuring instrument 9.

Then, the thickness of the mask frame 2 polished by the polishing apparatus 13 is measured, and the lifting amount of the mask frame 2 is determined on the basis of the measured value of the thickness. Thus, when the mask frame 2 with the vapor deposition mask 3 removed for washing is polished by the polishing apparatus 13, the lifting amount of the mask frame 2 is determined on the basis of the thickness of the mask frame 2 after polishing. For example, when a reduction in thickness of the mask frame 2 by mechanical polishing is about 0.1 mm per polishing and the dimensional tolerance of the thickness of the mask frame 2 after mechanical polishing is 30.0 mm plus 0.2 mm, minus 0.35 mm, the lifting amount of the mask frame 2 is determined on the basis of the dimensional tolerance of the thickness after mechanical polishing and the thickness of the mask frame 2 measured after mechanical polishing. Thus, the allowable specifications of the thickness of the mask frame 2 can be made more flexible by controlling the gap between the touch plate 5 and the vapor deposition mask 3 so as to be constant, in accordance with the thickness of the mask frame 2 after polishing.

In the past, the thickness of the mask frame 2 had a range in which use was permitted. For example, when the mask frame 2 was polished two to three times, the thickness normally decreased by about from 0.5 mm to 1 mm, making the mask frame 2 unsuitable for use.

According to the present embodiment, the lifting amount is determined in accordance with the thickness of the mask frame 2, and thus a force by which the vapor deposition mask 3 fixed to the mask frame 2 comes into contact with the substrate 4 is suppressed. As a result, a state in which excessive force is applied to the substrate 4 no longer exists. Accordingly, the possibility of breakage and chipping of the substrate 4 is reduced. Then, even when polishing of the mask frame 2, which reduces the thickness from 100 to 200 μm per polishing, is implemented four or more times, continual use of the mask frame 2 is possible. As a result, the cost of the mask frame 2 in the OLED process can be reduced.

The thickness of the mask frame 2 polished by the polishing apparatus 13 may be measured after the vapor deposition mask 3 washed by the washing apparatus 12 is once again welded and fixed to the mask frame 2, and the mask frame 2 onto which the vapor deposition mask 3 is fixed is delivered into the vacuum chamber 6.

While the above has illustrated an example in which the mask frame 2 is polished with the vapor deposition mask 3 removed in order to wash a portion of the luminescent material adhered to the vapor deposition mask 3, the disclosure is not limited thereto. For example, the vapor deposition apparatus may be configured so that the thickness of the mask frame 2 after polishing is measured when the mask frame 2 is polished with the vapor deposition mask 3 removed in order to replace the vapor deposition mask 3 used in the vapor deposition process.

### Second Embodiment

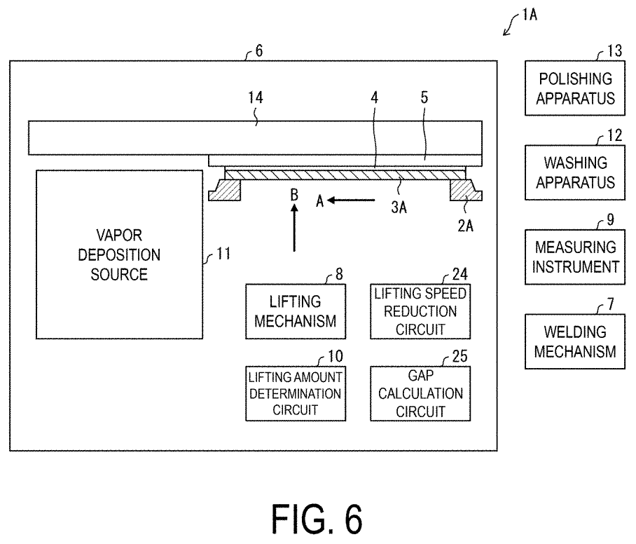

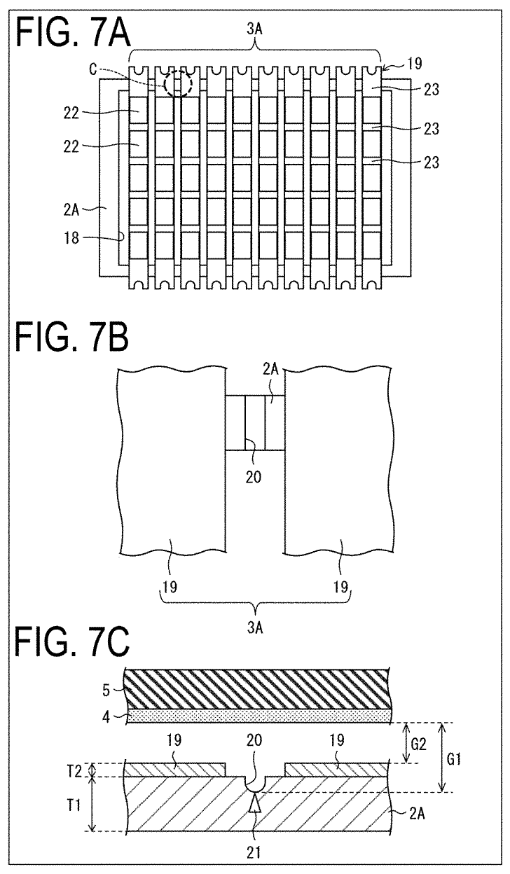

FIG. 6 is a schematic view illustrating a configuration of a vapor deposition apparatus 1A according to the second embodiment. FIG. 7A is a plan view of a mask frame 2A and a vapor deposition mask 3A provided to the vapor deposition apparatus 1A, FIG. 7B is a plan view illustrating the details of a portion C of FIG. 7A, and FIG. 7C is a cross-sectional view for describing the details of the portion C in FIG. 7A. The constituent elements that are the same as the constituent elements described in the first embodiment are denoted using the same reference numerals. Detailed descriptions of these constituent elements are not repeated.

The vapor deposition apparatus 1A includes the mask frame 2A formed into a frame shape surrounding an opening 18 having a rectangular cross-sectional shape.

The vapor deposition apparatus 1A is provided with the vapor deposition mask 3A. The vapor deposition mask 3A includes a plurality of divided sheets 19, each having a strip shape and extending parallel with each other across the opening 18 at a predetermined interval. In each of the divided sheets 19, a plurality of effective regions 22 are arranged at a predetermined interval in a longitudinal direction. In each of the plurality of effective regions 22, a plurality of through-holes (not illustrated) for allowing particles to be vapor-deposited pass therethrough are formed. The effective regions 22 each correspond to one OLED panel. Then, peripheral regions 23 are arranged so as to surround each of the effective regions 22.

The mask frame 2A includes a recessed portion 20 having a groove shape and formed in the longitudinal direction of the divided sheets 19, between the plurality of divided sheets 19.

The substrate 4 is disposed above the mask frame 2A. Then, the touch plate 5 is disposed on a side of the substrate 4 opposite to the mask frame 2A side. Then, a gap measuring instrument 21 that measures a gap G1 between the substrate 4 and a bottom face of the recessed portion 20 of the mask frame 2A is formed so as to be exposed to the bottom face of the recessed portion 20.

The vapor deposition apparatus 1A is provided with a gap calculation circuit 25 that calculates a gap G2 between the substrate 4 and the divided sheets 19 on the basis of the gap G1 measured by the gap measuring instrument 21, a thickness T2 of the divided sheet 19, and a thickness T1 of the mask frame 2A measured by the measuring instrument 9, and a lifting speed reduction circuit 24 that reduces the lifting speed of the mask frame 2A when the gap G2 calculated by the gap calculation circuit 25 reaches a predetermined threshold value.

According to the vapor deposition apparatus 1A thus configured, first the divided sheets 19 are removed from the mask frame 2A in order to wash or replace the divided sheets 19. Then, a joining face of the mask frame 2A with the divided sheets 19 is polished by the polishing apparatus 13. Next, the thickness T1 of the mask frame 2A after polishing is measured by the measuring instrument 9.

Subsequently, the lifting mechanism 8 lifts the mask frame 2A while the gap measuring instrument 21 measures the gap G1 between the substrate 4 and the bottom face of the recessed portion 20 formed on the mask frame 2A. Then, the gap calculation circuit 25 calculates the gap G2 between the divided sheets 19 and the substrate 4 on the basis of the thickness T2 of the divided sheet 19 set in advance, the thickness T1 of the mask frame 2A measured by the measuring instrument 9, and the gap G1 measured by the gap measuring instrument 21.

When the gap G2 calculated by the gap calculation circuit 25 reaches a predetermined threshold value, the lifting speed reduction circuit 24 reduces the lifting speed of the mask frame 2A. The predetermined threshold value is set to about from 100 to 300 μm. As a result, the divided sheets 19 gently come into contact with the substrate 4.

Similar to the first embodiment, the lifting amount determination circuit 10 may determine the lifting amount of the mask frame 2A on the basis of the thickness of the mask frame 2A measured by the measuring instrument 9.

### Supplement

A vapor deposition method according to a first aspect includes a fixing step for fixing a vapor deposition mask on a mask frame, a lifting step for mounting a substrate on the vapor deposition mask fixed on the mask frame and lifting the mask frame, bringing the substrate into contact with a touch plate disposed above the mask frame, and a measurement step for measuring a thickness of the mask frame. The lifting step includes determining a lifting amount of the mask frame on the basis of the thickness of the mask frame measured by the measurement step.

According to a second aspect, the mask frame is formed into a frame shape surrounding an opening, and the vapor deposition mask includes a plurality of divided sheets, each having a strip shape and extending across the opening.

According to a third aspect, the mask frame includes a recessed portion formed between the plurality of divided sheets, and the lifting step includes a gap measurement step for measuring a gap between the substrate and a bottom face of the recessed portion of the mask frame while lifting the mask frame, and a lifting speed reduction step for reducing a lifting speed of the mask frame when the gap measured by the gap measurement step reaches a predetermined threshold value.

According to a fourth aspect, the vapor deposition method further includes a vapor deposition step for vapor-depositing a luminescent material onto the substrate through the vapor deposition mask fixed on the mask frame by welding lifted by the lifting step, a washing step for removing the vapor deposition mask from the mask frame and washing a portion of the luminescent material adhered to the vapor deposition mask, a polishing step for polishing the mask frame with the vapor deposition mask removed, and a re-welding step for once again welding and fixing the vapor deposition mask washed in the washing step to the mask frame polished in the polishing step. Furthermore, in this vapor deposition method, the fixing step includes fixing the vapor deposition mask on the mask frame by welding.

According to a fifth aspect, the vapor deposition method further includes a vapor deposition step for vapor-depositing a luminescent material onto the substrate through the vapor deposition mask fixed on the mask frame by welding lifted by the lifting step, a removing step for removing the vapor deposition mask used in the vapor deposition step from the mask frame in order to replace the vapor deposition mask, a polishing step for polishing the mask frame with the vapor deposition mask removed, and a replacement step for welding and fixing the vapor deposition mask for replacement to the mask frame polished in the polishing step. Furthermore, in this vapor deposition method, the fixing step includes fixing the vapor deposition mask on the mask frame by welding.

According to a sixth aspect, the measurement step measures a thickness of the mask frame before the vapor deposition mask is fixed.

According to a seventh aspect, the measurement step measures a thickness of the mask frame after the vapor deposition mask is fixed.

According to an eighth aspect, the measurement step measures a thickness of the mask frame polished by the polishing step.

A vapor deposition apparatus according to a ninth aspect includes a lifting mechanism configured to mount a substrate on a vapor deposition mask fixed on a mask frame and lift the mask frame to bring the substrate into contact with a touch plate disposed above the mask frame, a measuring instrument configured to measure a thickness of the mask frame, and a lifting amount determination circuit configured to determine a lifting amount of the mask frame on the basis of the thickness of the mask frame measured by the measuring instrument.

An EL device manufacturing apparatus according to a tenth aspect includes a lifting mechanism configured to mount a substrate on a vapor deposition mask fixed on a mask frame and lift the mask frame to bring the substrate into contact with a touch plate disposed above the mask frame, a measuring instrument configured to measure a thickness of the mask frame, a lifting amount determination circuit configured to determine a lifting amount of the mask frame on the basis of the thickness of the mask frame measured by the measuring instrument, and a vapor deposition source configured to vapor-deposit a vapor deposition layer for an EL device onto the substrate through the vapor deposition mask fixed to the mask frame lifted by the lifting mechanism.

An EL device manufacturing method according to an eleventh aspect includes a lifting step for mounting a substrate on a vapor deposition mask fixed on a mask frame and lifting the mask frame to bring the substrate into contact with a touch plate disposed above the mask frame, a measurement step for measuring a thickness of the mask frame, a lifting amount determination step for determining a lifting amount of the mask frame on the basis of the thickness of the mask frame measured by the measurement step, and a vapor deposition step for vapor-depositing a vapor deposition layer for an EL device onto the substrate through the vapor deposition mask fixed to the mask frame lifted by the lifting step.

A vapor deposition method according to a twelfth aspect includes a fixing step for fixing a vapor deposition mask on a mask frame, and a lifting step for lifting the mask frame to bring the vapor deposition mask into contact with a substrate disposed above the mask frame. The mask frame is formed into a frame shape surrounding an opening. The vapor deposition mask includes a plurality of divided sheets, each having a strip shape and extending across the opening. The mask frame includes a recessed portion formed between the plurality of divided sheets. The lifting step includes a gap measurement step for measuring a gap between the substrate and a bottom face of the recessed portion of the mask frame while lifting the mask frame, and a lifting speed reduction step for reducing a lifting speed of the mask frame when the gap measured by the gap measurement step reaches a predetermined threshold value.

The disclosure is not limited to each of the embodiments stated above, and various modifications may be implemented within a range not departing from the scope of the claims. Embodiments obtained by appropriately combining technical approaches stated in each of the different embodiments also fall within the scope of the technology of the disclosure. Moreover, novel technical features may be formed by combining the technical approaches stated in each of the embodiments.

### REFERENCE SIGNS LIST

1 Vapor deposition apparatus

2 Mask frame

3 Vapor deposition mask

4 Substrate

5 Touch plate

6 Vacuum chamber

7 Welding mechanism (fixing mechanism)

8 Lifting mechanism

9 Measuring instrument

10 Lifting amount determination circuit

11 Vapor deposition source

12 Washing apparatus

13 Polishing apparatus

18 Opening

19 divided sheet

20 Recessed portion

21 Gap measuring instrument

24 Lifting speed reduction circuit

1. A vapor deposition method comprising:
a fixing step for fixing a vapor deposition mask on a mask frame;
a lifting step for mounting a substrate on the vapor deposition mask fixed on the mask frame and lifting the mask frame to bring the substrate into contact with a touch plate disposed above the mask frame; and
a measurement step for measuring a thickness of the mask frame,
wherein the lifting step includes determining a lifting amount of the mask frame on the basis of the thickness of the mask frame measured by the measurement step.

2. The vapor deposition method according to claim 1,
wherein the mask frame is formed into a frame shape surrounding an opening, and
the vapor deposition mask includes a plurality of divided sheets, each having a strip shape and extending across the opening.

3. The vapor deposition method according to claim 2,
wherein the mask frame includes a recessed portion formed between the plurality of divided sheets, and
the lifting step includes a gap measurement step for measuring a gap between the substrate and a bottom face of the recessed portion of the mask frame while lifting the mask frame, and
a lifting speed reduction step for reducing a lifting speed of the mask frame when the gap measured by the gap measurement step reaches a predetermined threshold value.

4. The vapor deposition method according to claim 1, further comprising:
a vapor deposition step for vapor-depositing a luminescent material onto the substrate through the vapor deposition mask fixed to the mask frame lifted by the lifting step;
a washing step for removing the vapor deposition mask from the mask frame and washing a portion of the luminescent material adhered to the vapor deposition mask;
a polishing step for polishing the mask frame with the vapor deposition mask removed; and
a re-welding step for once again welding and fixing the vapor deposition mask washed in the washing step to the mask frame polished in the polishing step,
wherein the fixing step includes fixing the vapor deposition mask on the mask frame by welding.

5. The vapor deposition method according to claim 1, further comprising:
a vapor deposition step for vapor-depositing a luminescent material onto the substrate through the vapor deposition mask fixed to the mask frame lifted by the lifting step;
a removing step for removing the vapor deposition mask used in the vapor deposition step from the mask frame in order to replace the vapor deposition mask;
a polishing step for polishing the mask frame with the vapor deposition mask removed; and
a replacement step for welding and fixing the vapor deposition mask for replacement to the mask frame polished in the polishing step,
wherein the fixing step includes fixing the vapor deposition mask on the mask frame by welding.

6. The vapor deposition method according to claim 1,
wherein the measurement step includes measuring a thickness of the mask frame before the vapor deposition mask is fixed.

7. The vapor deposition method according to claim 1,
wherein the measurement step includes measuring a thickness of the mask frame after the vapor deposition mask is fixed.

8. The vapor deposition method according to claim 4,
wherein the measurement step includes measuring a thickness of the mask frame polished by the polishing step.

9-10 (canceled)

11. An EL device manufacturing method comprising:
a lifting step for mounting a substrate on a vapor deposition mask fixed on a mask frame and lifting the mask frame to bring the substrate into contact with a touch plate disposed above the mask frame;
a measurement step for measuring a thickness of the mask frame;
a lifting amount determination step for determining a lifting amount of the mask frame on the basis of the thickness of the mask frame measured by the measurement step; and
a vapor deposition step for vapor-depositing a vapor deposition layer for an EL device onto the substrate through the vapor deposition mask fixed to the mask frame lifted by the lifting step.

12. A vapor deposition method comprising:
a fixing step for fixing a vapor deposition mask on a mask frame; and
a lifting step for lifting the mask frame to bring the vapor deposition mask into contact with a substrate disposed above the mask frame,
wherein the mask frame is formed into a frame shape surrounding an opening,
the vapor deposition mask includes a plurality of divided sheets, each having a strip shape and extending across the opening,
the mask frame includes a recessed portion formed between the plurality of divided sheets, and
the lifting step includes a gap measurement step for measuring a gap between the substrate and a bottom face of the recessed portion of the mask frame while lifting the mask frame, and
a lifting speed reduction step for reducing a lifting speed of the mask frame when the gap measured by the gap measurement step reaches a predetermined threshold value.
